(19) United States
(12) Patent Application Publication
(10) Pub. No.: US 2026/0363061 A1
(43) Pub. Date: Nov. 12, 2026

(54) SEMICONDUCTOR STRUCTURE WITH THIN FILM RESISTOR AND METHOD FOR MANUFACTURING THE SAME

(71) Applicant: TAIWAN SEMICONDUCTOR MANUFACTURING COMPANY, LTD., Hsinchu (TW)

(72) Inventors: Kun-Yen LIAO, Hsinchu (TW); Chia-Tien WU, Hsinchu (TW); Jian-Hua CHEN, Hsinchu (TW)

(73) Assignee: TAIWAN SEMICONDUCTOR MANUFACTURING COMPANY, LTD., Hsinchu (TW)

(21) Appl. No.: 19/201,120

(22) Filed: May 7, 2025

(51) Int. Cl. H10W 20/40; H10D 1/00; H10D 1/47

(52) U.S. Cl. CPC H10W 20/498; H10D 1/021; H10D 1/47

(57) ABSTRACT

A method for manufacturing a semiconductor structure includes: sequentially forming a resistive film and a conductive layer over a base structure; performing a first patterning process to form the conductive layer into a patterned conductive layer without patterning the resistive film; and performing a second patterning process to form the patterned conductive layer into a conductive pattern, and to form the resistive film into a resistive pattern, the resistive pattern having a first resistive portion including a first resistive part that has a first end, a second end, and a main region disposed between the first end and the second end, the conductive pattern having a first conductive portion including a first conductive part that is disposed on the first end of the first resistive part without covering the main region, and the first resistive portion and the first conductive portion together forming a resistive feature.

### BACKGROUND

Resistors are passive components of integrated circuits (ICs), and have essential functions in voltage division, current limiting, and biasing. Resistors regulate current flow by providing resistance, facilitating in maintenance of proper voltage levels across various components, and protecting sensitive parts of ICs from excessive current.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 19 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects±20%, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions and could be understood by those skilled in the art after reviewing the present disclosure.

The term “source/drain region(s)” may refer to a source or a drain, individually or collectively dependent upon the context.

In advanced technology nodes, a high-resistance (high-R) resistor located at a back-end-of-line (BEOL) section is adopted to replace a gate polysilicon resistor to allow some areas in a front-end-of-line (FEOL) section to be made available for other purposes. However, the high-R resistor in the BEOL section is formed with a relatively large thickness, which may lead to topography issue. In order to avoid reliability and thermal issues, no signal lines is provided immediately above and below the high-R resistor, and thus the placement of the high-R resistor will waste routing resources. In addition, such topography issue causes local stress and impacts the nearby circuit pattern. Further, an electrical connection path for connecting the high-R resistor with a device at the FEOL section is relatively long and exhibits a relatively large resistance, which may adversely affect the performance of the high-R resistor, e.g., an operation speed.

The present disclosure is directed to a semiconductor structure including a base structure, and an interconnect level disposed on the base structure. The interconnect level includes a resistive feature and an interconnect feature that is spaced apart from the resistive feature. The resistive feature includes a first conductive portion and a first resistive portion that is partially covered by the first conductive portion. Such resistive feature serves as a high-R thin-film resistor. The interconnect feature includes a second conductive portion and a second resistive portion that is approximately entirely covered by the second conductive portion. The resistive feature and the interconnect feature are formed from a material stack including a resistive film and a conductive layer that are sequentially disposed on the base structure. A first patterning process is performed to form the conductive layer into a patterned conductive layer without patterning the resistive film. Subsequently, a second patterning process, e.g., a direct metal etching process, but is not limited thereto, is performed to form the patterned conductive layer into a conductive pattern, and to form the resistive film into a resistive pattern. The conductive pattern includes the first and second conductive portions, while the resistive pattern includes the first and second resistive portions. As such, the resistive feature and the interconnect feature are obtained. It is noted that the resistive film is significantly thin, so as to avoid topography issue, and so that the resistive feature and the interconnect feature achieve desired electrical properties. In addition, the interconnect level may be placed closed to a semiconductor device in the base structure, so as to ensure a short conduction path, and low resistance level between the resistive feature and the semiconductor device. The resultant semiconductor structure may have an enhanced performance, e.g., a high operation speed. Moreover, the production cost is low because only one patterning mask is required in the second patterning process to obtain both the interconnect feature and the resistive feature.

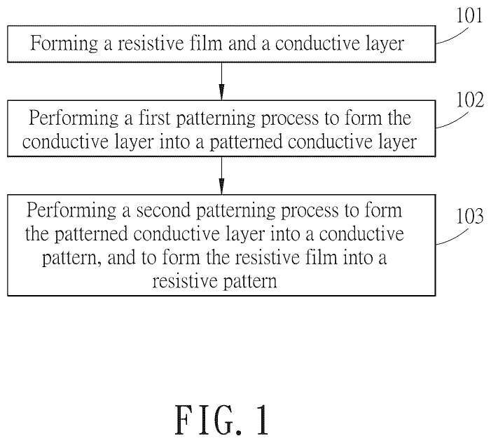

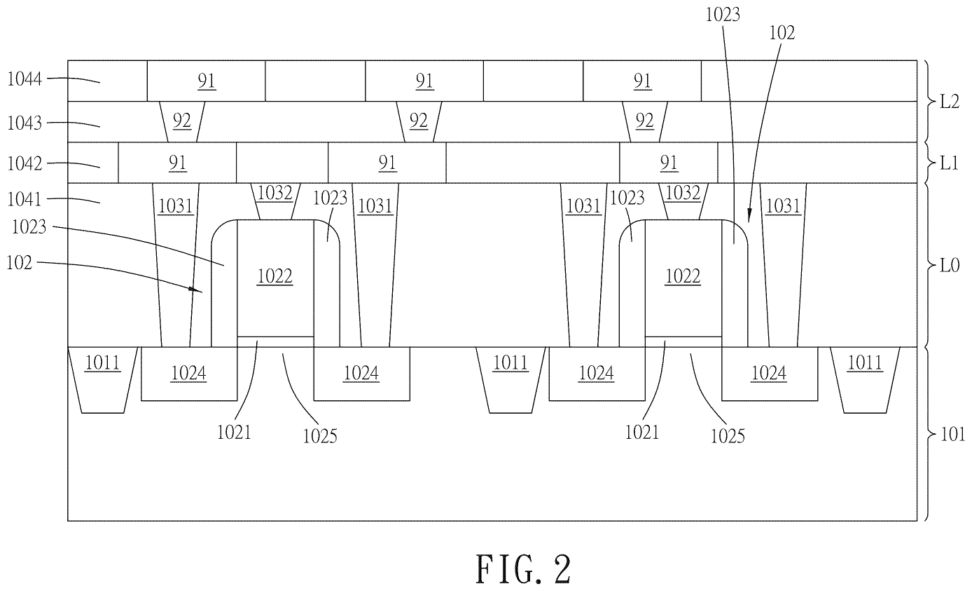

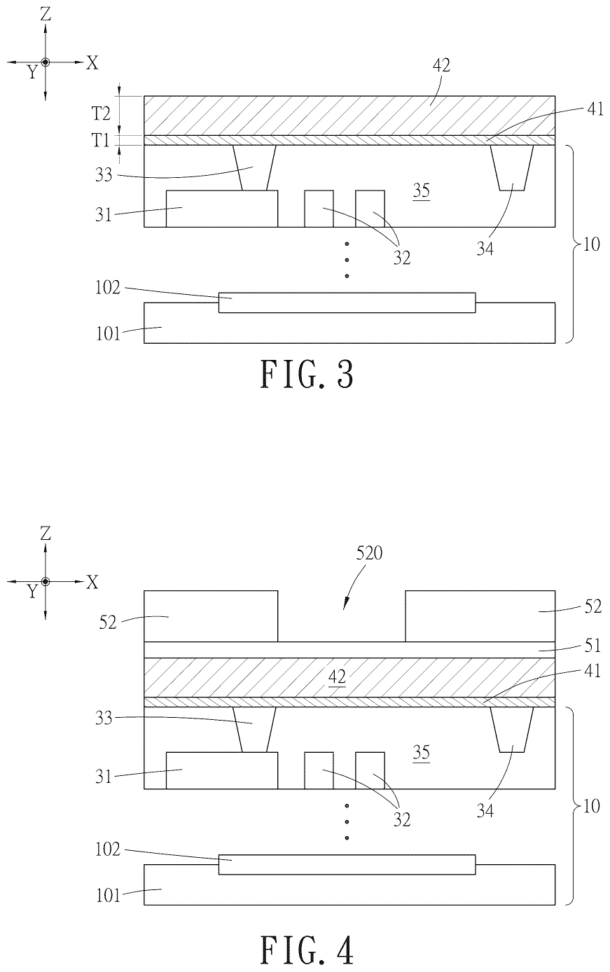

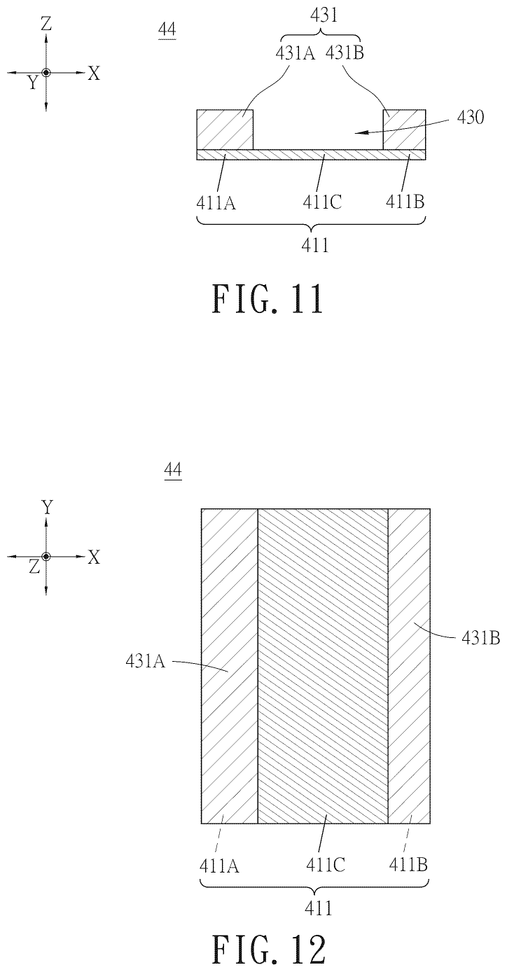

FIG. 1 is a flow diagram illustrating a method for manufacturing the semiconductor structure (for example, the semiconductor structure shown in FIGS. 11, 14, or 15) in accordance with some embodiments. FIG. 2 is a schematic view of a plurality of levels in a semiconductor structure in accordance with some embodiments, and may not reflect an actual sectional view of the semiconductor structure. FIGS. 3 to 19 illustrate schematic views of intermediate stages of the method in accordance with some embodiments, and the structures shown in FIGS. 3 to 19 are obtained by the steps that are also illustrated in the flow diagram shown in FIG. 1. Some repeating structures are omitted in FIGS. 2 to 19 for the sake of brevity. Additional steps can be provided before, after or during the method, and some of the steps described herein may be replaced by other steps or be eliminated.

Referring to FIG. 2, in some embodiments, the semiconductor structure includes a substrate 101, a plurality of semiconductor devices 102 formed on the substrate 101, a plurality of source/drain contacts 1031, a plurality of gate contacts 1032, and a dielectric layer 1041. In some embodiments, the substrate 101 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 101 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 101 may be configured as a semiconductor-on-insulator substrate. Other suitable materials and configurations for the substrate 101 are within the contemplated scope of the present disclosure. In some embodiments, the substrate 101 may be formed with trench isolations 1011 to separate each of the semiconductor devices 102 from adjacent ones of the semiconductor devices. In some embodiments, the trench isolations 1011 may each be a shallow trench isolation (STI), a deep trench isolation (DTI), or other suitable structures. In some embodiments, the trench isolations 1011 may include silicon oxide, silicon nitride, silicon oxynitride, other low-k (low-dielectric constant) dielectric materials, or combinations thereof. The semiconductor devices 102 may be active devices (for example, transistors, diodes, or the like), passive devices (for example, capacitors, inductors, resistors, or the like), memory devices, decoders, amplifiers, other suitable devices, or combinations thereof. In some embodiments, the semiconductor devices 102 may be transistors, such as a metal oxide semiconductor field effect transistor (MOSFET). Although the semiconductor devices 102 shown in FIG. 2 are each exemplified as a planar transistor, the semiconductor devices 102 may each be a fin-type field-effect transistor (FinFET), a gate-all-around field-effect transistor (GAAFET), a forksheet field-effect transistor, a complementary field-effect transistor (CFET), other transistors with suitable configurations, or other suitable devices. In some embodiments, each of the transistors 102 may have two source/drain regions 1024 formed in the substrate 101, a channel 1025 located between the two source/drain regions 1024, a gate structure interfacing the channel 1025. The gate structure is formed in the dielectric layer 1041 in a contact-level structure L0, and has a gate dielectric layer 1021 formed over the channel 1025, a gate electrode 1022 formed over the gate dielectric layer 1021, and two spacers 1023 formed respectively at two opposite sides of the gate electrode 1022. The gate dielectric layer 1021 may include or may be made of silicon oxide, silicon nitride, silicon oxynitride, a suitable high-k material (such as hafnium oxide, zirconium oxide, zirconium aluminum oxide, hafnium aluminum oxide, hafnium silicon oxide, aluminum oxide, and so on), other suitable materials, or combinations thereof. The gate electrode 1022 may include or may be made of a metal material (e.g., tungsten (W), titanium (Ti), tantalum (Ta), aluminum (Al), or ruthenium (Ru)), metal-containing nitrides (e.g., titanium nitride (TiN), or tantalum nitride (TaN)), metal-containing silicides (e.g., nickel silicide (NiSi)), metal-containing carbides (e.g., tantalum carbide (TaC)), other suitable materials, or combinations thereof. In some embodiments, the gate electrode 1022 may include or may be made of various n-type or p-type work function metals. Examples of the n-type work function metal include Al, titanium aluminium carbide (TiAlC), TiAl, or other suitable materials. Examples of p-type work function metal include TiN, tungsten nitride (WN), tungsten carbon nitride (WCN), molybdenum nitride (MoN), or other suitable materials. The spacers 1023 may include or may be made of a nitride-based material, such as silicon nitride, silicon oxynitride, silicon carbon nitride, silicon oxycarbonnitride, other suitable materials, or combinations thereof. The semiconductor devices 102 may be electrically connected to external circuits through the source/drain contacts 1031 and the gate contacts 1032 formed in the dielectric layer 1041. In some embodiments, the dielectric layer 1041 includes or is made of a low-k dielectric material. In some embodiments, the dielectric layer 1041 includes or is made of a dielectric material, such as silicon oxide, silicon nitride, silicon carbide, silicon carbonitride, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. Other dielectric materials suitable for the dielectric layer 1041 are within the contemplated scope of the present disclosure. In some embodiments, each of the source/drain contacts 1031 and the gate contacts 1032 includes or is made of Cu, Co, Ru, Mo, Cr, W, Mn, Rh, Ir, Ni, Pd, Ag, Au, Al, alloys thereof, graphene, other suitable conductive materials, or combinations thereof. In some embodiments, each of the source/drain contacts 1031 and the gate contacts 1032 may be formed by a single damascene process involving physical vapor deposition (hereinafter PVD), chemical vapor deposition (hereinafter CVD), atomic layer deposition (hereinafter ALD) or other suitable processes. In some embodiments, the semiconductor structure further includes one or multiple interconnect-level structures L1, L2, L3, . . . Ln (L3 to Ln are not shown). In the interconnect-level structure L1, metal lines 91 are formed in a dielectric layer 1042. In each of the interconnect-level structures L2 to Ln, metal vias 92 are formed in a dielectric layer 1043, and metal lines 91 are formed in a dielectric layer 1044. Suitable materials for the metal lines 91 and the metal vias 92 are similar to those for the source/drain contacts 1031 and the gate contacts 1032, Suitable materials for the dielectric layers 1042, 1043, 1044 are similar to those for the dielectric layer 1041.

Referring to FIG. 3, a base structure 10 is shown. The base structure 10 includes the substrate 101, the semiconductor devices 102 (one of which is shown and located at the FEOL section), a conductive feature 31, alignment features 32, conductive vias 33, 34, and a dielectric layer 35. The conductive feature 31, the alignment features 32, the conductive vias 33, 34 are formed in the dielectric layer 35. In some embodiments, the conductive feature 31, the alignment features 32, and the conductive vias 33, 34 may be located in the contact-level structure L0 shown in FIG. 2, and the conductive feature 31 may serve as one of the source/drain contacts 1031 (in such case, the contact-level structure L0 may have the conductive feature 31 and the conductive vias 33, 34 at different horizontal positions as shown in FIG. 3). In some other embodiments, the conductive feature 31 and the alignment features 32 may be located in one of the interconnect-level structures L1 to Ln (only L1 and L2 are shown in FIG. 2), and the conductive feature 31 may serve as one of the metal lines 91; while the conductive vias 33, 34 may each serve as one of the metal vias 92 located at an adjacent one of the interconnect-level structures L2 to Ln (only L2 is shown in FIG. 2). In certain embodiments, the dielectric layer 35 shown in FIG. 3 may serve as corresponding one(s) of the dielectric layers 1041 to 1044 shown in FIG. 2. Other suitable elements for the base structure 10 are within the contemplated scope of the present disclosure.

In the following description, the semiconductor devices 102 are described in singular form for the sake of brevity. The alignment features 32 are configured for alignment purpose in subsequent steps, and may be formed together with the conductive feature 31. The conductive via 33 is connected to the semiconductor device 102 through the conductive feature 31, but is not limited thereto. The conductive via 34 is connected to another semiconductor device (not shown in FIG. 3). Please note that a number and/or configuration and/or connection of each of the conductive features 31 (one of which is shown), the alignment features 32 and the conductive vias 33, 34 may be varied according to practical needs.

Possible materials for each of the conductive feature 31, the alignment features 32, the conductive vias 33, 34 may include or may be made of a conductive material are similar to those for the source/drain contacts 1031, the gate contacts 1032, the metal lines 91 and the metal vias 92. Possible materials for the dielectric layer 35 are similar to those for the dielectric layers 1041 to 1044. Other suitable materials for forming the conductive features 31, the alignment features 32, the conductive vias 33, 34, the dielectric layer 35 are within the contemplated scope of the present disclosure.

Referring to FIG. 3, a material stack including a resistive film 41 and a conductive layer 42 is formed over the base structure 10 along a Z direction. The resistive film 41 is formed over the base structure 10 using a suitable deposition process, such as physical vapor deposition (PVD), chemical vapor deposition (CVD), atomic layer deposition (ALD), other suitable processes, or combinations thereof. In the following description, a deposition process, unless otherwise stated or defined in this disclosure, may be performed in a way similar to the above-mentioned ones. In some embodiments, the resistive film 41 is formed to entirely cover an upper surface of the base structure 10. The resistive film 41 includes or is made of an electrically resistive material, such as titanium nitride, titanium oxide, titanium oxynitride, tantalum nitride, tantalum oxide, tungsten carbon nitride, zirconium oxide, cobalt oxide, silicon nitride, boron nitride, or other suitable materials, or combinations thereof. The resistive film 41 has a thickness (T1) ranging from about 10 Å to about 50 Å (e.g., about 15 Å, about 20 Å, about 30 Å, about 40 Å).

The conductive layer 42 is formed over the resistive film 41 opposite to the base structure 10 using a suitable deposition process. The conductive layer 42 includes or is made of an electrically conductive material, such as ruthenium, tungsten, molybdenum, iridium, nickel aluminum, cobalt platinum, or other suitable materials, or combinations thereof. The conductive layer 42 has a thickness (T2) ranging from about 100 Å to about 400 Å (e.g., about 150 Å, about 200 Å, about 250 Å, about 300 Å, about 350 Å, about 400 Å).

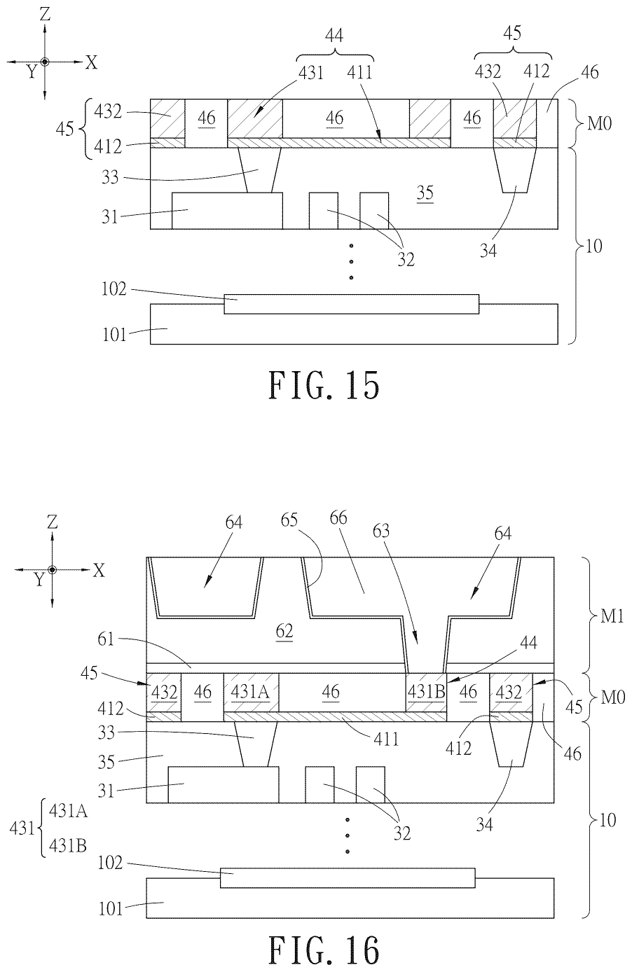

Please note that the material of the conductive layer 42 is different from the material of the resistive film 41. More specifically, an electrical conductivity of the conductive layer 42 is higher than an electrical conductivity of the resistive film 41, though both the conductive layer 42 and the resistive film 41 are electrically conductive. In other words, an electrical resistivity of the resistive film 41 is higher than an electrical resistivity of the conductive layer 42. Moreover, the thickness (T1) of the resistive film 41 is smaller than the thickness (T2) of the conductive layer 42. In some embodiments, a ratio of T2 to T1 may range from about 2:1 to about 40:1. The criticality for this range will be discussed later with reference to FIG. 15.

Referring to FIG. 4, a patterned photoresist layer 52 is formed over the structure shown in FIG. 3.

In some embodiments, prior to forming the patterned photoresist layer 52, a hard mask material layer 51 is formed using a suitable deposition process. The hard mask material layer 51 may include or may be made of silicon oxide, aluminum oxide, titanium nitride, titanium oxide, scandium oxide, yttrium oxide, lutetium oxide, lanthanum oxide, zinc oxide, strontium oxide, indium oxide, gallium oxide, erbium oxide, niobium oxide, silicon oxynitride, silicon nitride, polysilicon, amorphous silicon, a carbon-containing dielectric material, a nitride-containing dielectric material, a refractory metal or combinations, but are not limited thereto. The hard mask material layer 51 may have a single-layer structure, or a multi-layered structure according to practical needs.

The patterned photoresist layer 52 is formed by forming a photoresist layer (not shown) over the hard mask material layer 51 by, e.g., spin coating; and patterning the photoresist layer using a photomask or without a mask (e.g., ion-beam writing). After forming the patterned photoresist layer 52, an opening 520 is formed to partially expose the hard mask material layer 51. Please note that a number and/or location of the opening 520 may be varied according to practical needs.

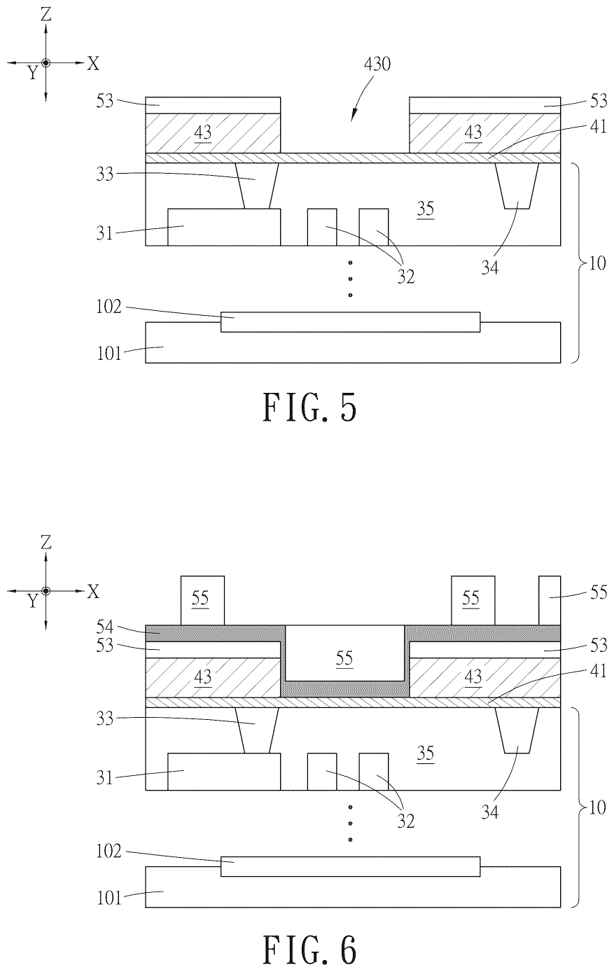

Referring to FIG. 5, a first patterning process is performed to form the conductive layer 42 (see also FIG. 4) into a patterned conductive layer 43 without patterning the resistive film 41.

In some embodiments, referring to FIGS. 4 and 5, the hard mask material layer 51 is patterned through the patterned photoresist layer 52 to form a patterned hard mask 53, and then the conductive layer 42 is patterned through the patterned hard mask 53 to form the patterned conductive layer 43. The conductive layer 42 may be patterned using an etching process, such as dry etching, wet etching, other suitable etching process, or combinations thereof. In the following description, an etching process, unless otherwise stated or defined in this disclosure, may be performed in a way similar to the above-mentioned ones. In the etching process, an etching rate of the conductive layer 42 is much higher than an etching rate of the resistive film 41. For example, the etching rate of the conductive layer 42 is at least about 50 times (e.g., about 75 times, 100 times, 125 times, 150 times, etc.,) higher than an etching rate of the resistive film 41. As such, a portion of the conductive layer 42 is removed, while the resistive film 41 may remain substantially intact. Afterwards, the patterned photoresist layer 52 is removed using an ashing process or other suitable processes.

After the first patterning process, the resistive film 41 is partially exposed from the patterned conductive layer 43 through an opening 430. The opening 430 corresponds in position to the opening 520 shown in FIG. 4.

Referring to FIG. 6, a patterned photoresist layer 55 is formed over the structure shown in FIG. 5.

After the first patterning process described with reference to FIG. 5, since the portion of the light-reflective conductive layer 42 shown in FIG. 4 is removed to form the opening 430, light can penetrate through the resistive film 41 and the dielectric layer 35 to reach the alignment features 32. In forming the patterned photoresist layer 55 shown in FIG. 6, the patterned photoresist layer 55 is aligned with elements underneath by utilizing the light and the alignment features 32, so as to achieve precise alignment and prevent overlay shift issue. The patterned photoresist layer 55 is formed in a manner similar to that of the patterned photoresist layer 52 described with reference to FIG. 3, and formation of the patterned photoresist layer 55 is not described for the sake of brevity.

In some embodiments, prior to forming the patterned photoresist layer 55, a mandrel layer 54 is formed by depositing a suitable material using a suitable deposition process.

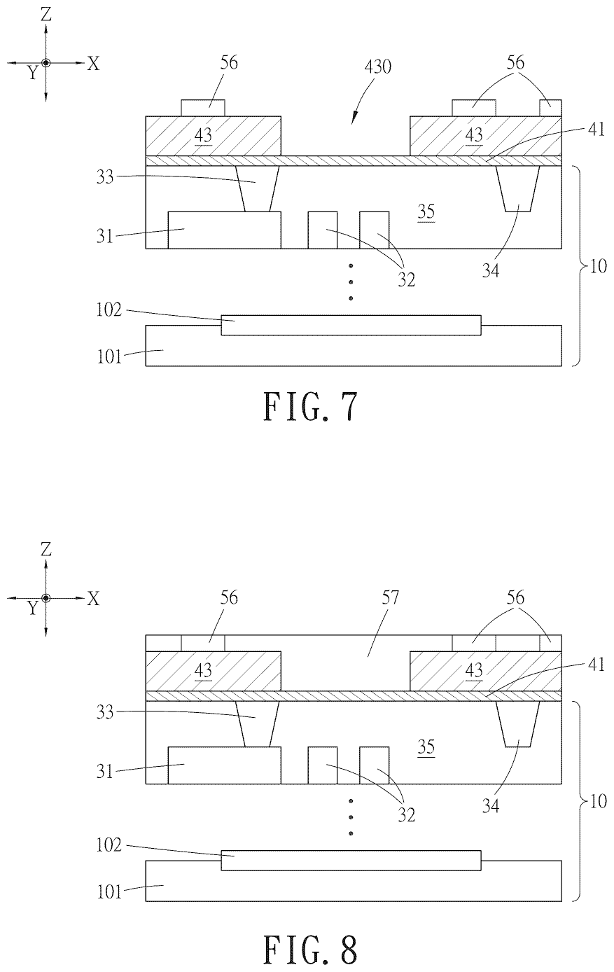

Referring to FIG. 7, the patterned hard mask 53 (see also FIG. 6) is further patterned into a mask pattern 56.

The mask pattern 511 may be formed using one or more suitable patterning process(es). For instance, a self-aligned double patterning (SADP) process is adopted involving patterning the mandrel layer 54 and the patterned hard mask 53 (see also FIG. 6) using the patterned photoresist layer 55 as an etching mask, and then removing the patterned mandrel layer 54 and the patterned photoresist layer 55. After the SADP process, the mask pattern 56 is obtained. Other suitable processes for forming the mask pattern 56 are within the contemplated scope of the present disclosure. After forming the mask pattern 56, the patterned conductive layer 43 is partially exposed from the mask pattern 56. In addition, the resistive film 41 is partially exposed through the opening 430.

Referring to FIG. 8, a gap filling layer 57 is formed over the structure shown in FIG. 7.

The gap filling layer 57 is formed using a suitable deposition process, followed by a planarization process (e.g., chemical mechanical planarization (CMP), but is not limited thereto). In some embodiments, the gap filling layer 57 may include or may be made of a carbon-based material, or an oxide-based material, such as silicon carbide, silicon oxide, silicon oxycarbide, or other suitable materials.

The gap filling layer 57 fills gaps of the mask pattern 56, as well as the opening 430 (see also FIG. 7). After forming the gap filling layer 57, the mask pattern 56 is exposed from the gap filling layer 57. The gap filling layer 57 facilitates sequential dual damascene process described with reference to FIG. 16.

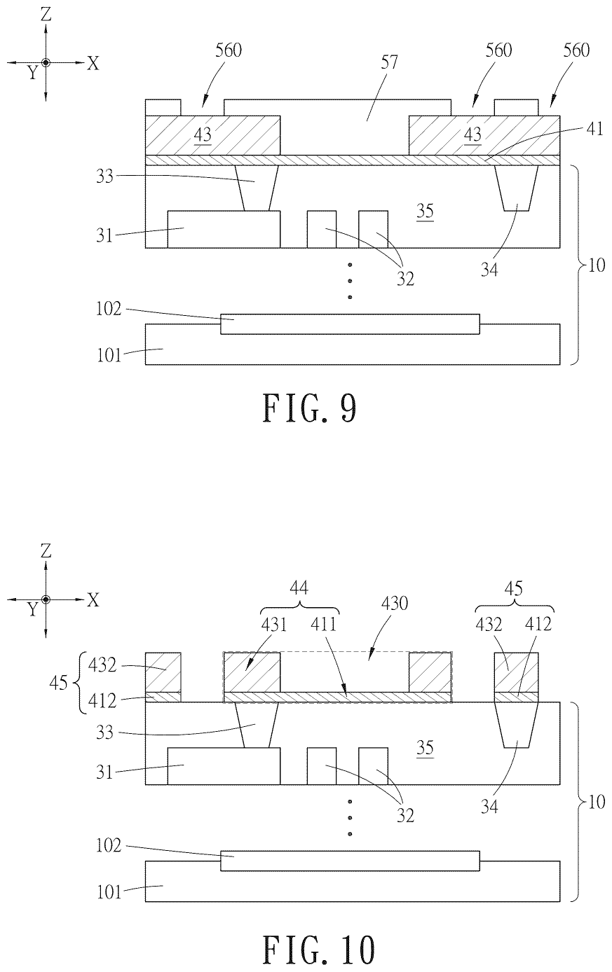

Referring to FIG. 9, the mask pattern 56 (see also FIG. 8) is removed to form openings 560 that respectively expose portions of the patterned conductive layer 43. The mask pattern 56 may be removed using a suitable process, such as an etching process, but is not limited thereto.

Referring to FIG. 10, a second patterning process is performed to form the patterned conductive layer 43 (see also FIG. 9) into a conductive pattern, and to form the resistive film 41 into a resistive pattern. The conductive pattern and the resistive pattern are defined by the gap filling layer 57 and the openings 560, positions of which are determined by the patterned photoresist layer 55 shown in FIG. 6.

The second patterning process may include two etching processes, each of which utilizes the gap filling layer 57 as an etching mask. In some embodiments, the two etching processes may each be a direct metal etching process, and the resistive film 41 and the conductive layer 42 are made of materials that can be etched using the direct metal etching process. In a first etching process, a first etchant is applied to pattern the patterned conductive layer 43 into the conductive pattern. An etching rate of the patterned conductive layer 43 is higher than an etching rate of the resistive film 41. In a second etching process, a second etchant is applied to pattern the resistive film 41 into the resistive pattern. An etching rate of the resistive film 41 is higher than an etching rate of the conductive pattern. Afterwards, the gap filling layer 57 is removed.

Referring to FIG. 10, the resistive pattern has a first resistive portion 411 and a second resistive portion 412 that is spaced apart from the first resistive portion 411. The conductive pattern has a first conductive portion 431 and a second conductive portion 432 that is spaced apart from the first conductive portion 431. The first and second conductive portions 431, 432 are disposed on the first and second resistive portions 411, 412, respectively. A number of the first resistive portion 411 is equal to a number of the first conductive portion 431, and may be varied according to practical needs. A number of the second resistive portion 412 is equal to a number of the second conductive portion 432, and may be varied according to practical needs. In the exemplary embodiment shown in FIG. 10, the number of the first resistive portion 411 is one, the number of the first conductive portion 431 is one, the number of the second resistive portion 412 is two, and the number of the second conductive portion 432 is two.

The first resistive portion 411 and the first conductive portion 431 together form a resistive feature 44 which is indicated by a dotted line in FIG. 10. FIG. 11 is an enlarged view of the resistive feature 44 shown in FIG. 10 in accordance with some embodiments, and illustrates a cross sectional view of the resistive feature 44. FIG. 12 is a top view of the resistive feature 44 (not drawn in scale) in accordance with some embodiments. Referring to FIGS. 10 to 12, the first resistive portion 411 is partially covered by the first conductive portion 431. The first conductive portion 431 may occupy not greater than about 30%, such as about 10% to about 30%, about 10% to about 20%, of an area of a top surface of the first resistive portion 411. Specifically, the first resistive portion 411 includes a resistive part that has a first end 411A, a second end 411B opposite to the first end 411A along an X direction, and a main region 411C located between the first end 411A and the second end 411B. At least one of the first end 411A and the second end 411B is covered by the first conductive portion 431, while the main region 411C steers clear of the first conductive portion 431. In some embodiments, the first conductive portion 431 includes a first conductive part 431A and a second conductive part 431B that are respectively disposed on the first end 411A and the second end 411B of the resistive part without covering the main region 411C. In other words, at least the main region 411C of the first resistive portion 411 is exposed from the first conductive portion 431 through the opening 430.

Each of the second resistive portions 412 and a respective one of the second conductive portion 432 together form an interconnect feature 45. Each of the second resistive portions 412 is substantially entirely covered by the respective one of the second conductive portions 432. The second conductive portion 432 may occupy not less than 90%, such as about 90% to about 100%, of an area of a top surface of the second resistive portion 412. The interconnect feature 45 may have a pitch that is greater than approximately 0 nm and smaller than approximately 50 nm, but is not limited thereto.

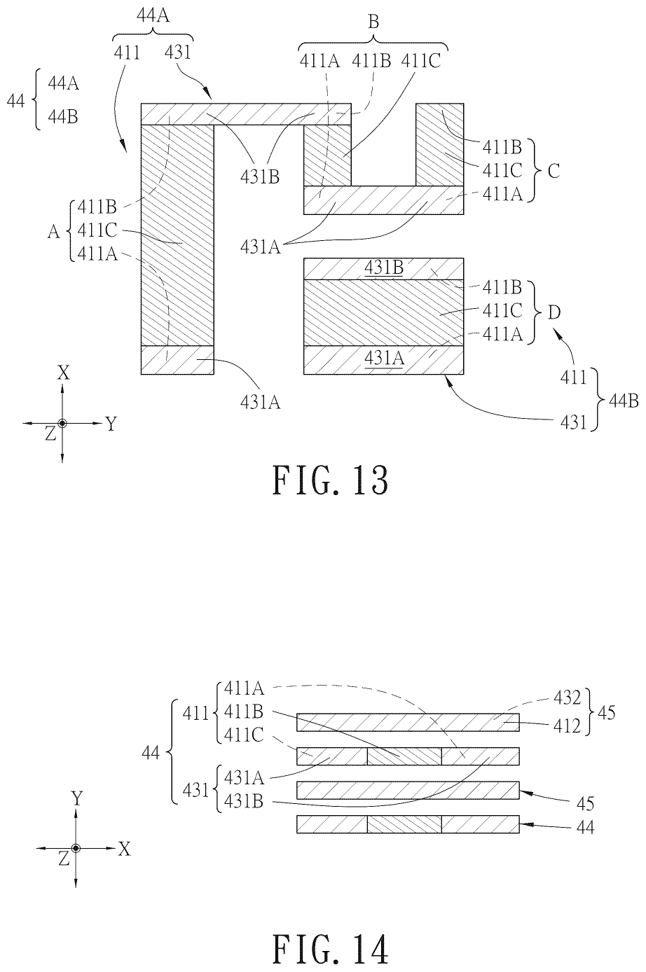

It should be noted that a number and/or arrangement of the first resistive portion(s) 411 and the first conductive portion(s) 431 may be varied according to practical needs. FIG. 13 is a top view illustrating two of the first resistive portions 411 and two of the first conductive portions 431 in accordance with some other embodiments of the present disclosure. Each of the first resistive portions 411, and a respective one of the first conductive portions 431 together form the resistive feature 44, i.e., two the resistive features, namely 44A, 44B, are shown in FIG. 13.

For the resistive feature 44A, the first resistive portion 411 thereof has resistive parts (A), (B), and (C). Each of the resistive parts (A), (B), and (C) has the first end 411A, the second end 411B, and the main region 411C disposed between the first end 411A and the second end 411B. The first end 411A and the second end 411B are opposite to each other in the X direction. The first conductive portion 431 of the resistive feature 44A has three the first conductive parts 431A that are respectively disposed on the first ends 411A of the resistive parts (A), (B), and (C), and two the second conductive parts 431B that are respectively disposed on the second ends 411B of the resistive parts (A) and (B). The main regions 411C of the resistive parts (A), (B) and (C) are spaced apart from each other in a Y direction different from the X and Z directions. In some embodiments, the X, Y and Z directions may be perpendicular to one another. The second ends 411B of the resistive parts (A), (B) are connected to each other in the Y direction. Accordingly, the second conductive parts 431B disposed on the resistive parts (A), (B) are connected to each other in the Y direction. The first ends of 411A of the resistive parts (B), (C) are connected to each other in the Y direction. Accordingly, the first conductive parts 431A disposed on the resistive parts (B), (C) are connected to each other in the Y direction. Other suitable connections and/or arrangements of the resistive parts (A), (B), (C), and/or the first and second conductive parts 431A, 431B are within the contemplated scope of the present disclosure.

The resistive feature 44B is spaced apart from the resistive feature 44A. For the resistive feature 44B, the first resistive portion 411 thereof has a resistive part (D) that has the first end 411A, the second end 411B, and the main region 411C; and the conductive portion 431 of the resistive feature 44B has the conductive portions 431A, 431B that are respectively disposed on the first and second ends 411A, 411B.

It should be noted that a number and/or arrangement of the resistive feature(s) 44 and the interconnect feature(s) 45 may be varied according to practical needs. FIG. 14 is a top view illustrating two the resistive features 44 and two the interconnect features 45 in accordance with some other embodiments of the present disclosure. The resistive features 44 and the interconnect features 45 are respectively similar to those described in FIGS. 10 to 12, and details thereof are omitted for the sake of brevity. As shown in FIG. 14, the two resistive features 44 and the two interconnect features 45 are alternately arranged along the Y direction. Other suitable arrangement of the resistive feature(s) 44 and/or the interconnect feature(s) 45 are within the contemplated scope of the present disclosure.

Referring to FIG. 15, a dielectric layer 46 is formed over the structure shown in FIG. 10.

A dielectric material layer (not shown) may be formed over the structure shown in FIG. 10, followed by a planarization process (e.g., CMP) to remove an excess amount of the dielectric material layer, thereby obtaining the dielectric layer 46. Possible materials for forming the dielectric layer 46 are similar to those of the dielectric layer 35, and thus details thereof are not repeated for the sake of brevity. The dielectric layer 46 fills the opening 430, and spaces among the resistive feature 44 and the interconnect features 45. As such, the resistive feature 44 and the interconnect features 45 are separated from one another by the dielectric layer 46. In addition, for the resistive feature 44, a part of the first resistive portion 411 that is not covered by the first conductive portion 431, e.g., the main region 411C (see also FIG. 11), is covered by the dielectric layer 46. After forming the dielectric layer 46, the conductive pattern (i.e., the first and second conductive portions 431, 432) is exposed from the dielectric layer 46.

The first interconnect level M0 above the base structure 10 is thus formed, and includes both the resistive feature(s) 44 and the interconnect feature(s) 45 formed in the dielectric layer 46. Hereinafter, the resistive feature(s) 44 and the interconnect feature(s) 45 are each described in singular form. The resistive feature 44 and the interconnect feature 45 are obtained at the same time after performing the second patterning process using the same etching mask 57 (see also FIGS. 9 and 10). The resistive feature 44 and the interconnect feature 45 are made of the same materials, but have different electrical properties. Specifically, an electrical resistivity of the resistive feature 44 is higher than an electrical resistivity of the interconnect feature 45. In other words, an electrical conductivity of the interconnect feature 45 is higher than an electrical conductivity of the resistive feature 44. Such difference in electrical properties may be due to different amount ratios of the electrically conductive material to the electrically resistive material in each of the resistive feature 44 and the interconnect feature 45. It should be noted that the amount (and/or position) of the electrically conductive material (of the conductive layer 42, see also FIGS. 3 and 4) retained in the resistive feature 44 (and the interconnect feature 45) may be varied by varying (i) design of the patterned photoresist layer 52, and (ii) design of the patterned photoresist layer 55. Regarding (i), as shown in FIG. 4, the amount of the electrically conductive material being removed in the first patterning process is varied to define the opening 430 shown in FIG. 5. Regarding (ii), as shown in FIGS. 6 to 9, the design of the patterned photoresist layer 55 defines the mask pattern 56, the gap filling layer 57 and the openings 560, so that the amount of the electrically conductive material being removed in the second patterning process is varied to define the resistive feature 44 and the interconnect feature 45. In forming the resistive feature 44, a large amount of the electrically conductive material is removed in the first and second patterning processes, such that a small amount of the conductive material remains to serve as the first conductive portion 431 of the resistive feature 44. As aforementioned, the first conductive portion 431 may occupy merely less than approximately 30% of the area of the top surface of the first resistive portion 411. Such small amount of the conductive material in the resistive feature 44 ensures that the resistive feature 44 has a relatively high electrical resistivity in comparison with the electrical resistivity of the interconnect feature 45. Referring to FIG. 11, the small amount of the electrically conductive material (the first and second conductive parts 431A, 431B) serve as contacts of the resistive feature 44, such that the resistive feature 44 may be electrically connected to other elements of the semiconductor structure. In contrast, in forming the interconnect feature 45 (see also FIG. 10), most of the conductive material remains after the first and second patterning process, and serves as the second conductive portion 432 of the interconnect feature 45. As such, the second conductive portion 432 may occupy substantially 100% of the area of the top surface of the second resistive portion 412. The presence of large amount of the conductive material in the interconnect feature 45 ensures that the the interconnect feature 45 has a relatively high electrical conductivity in comparison with the electrical conductivity of the resistive feature 44. It should also be noted that the thickness (T1, see also FIG. 3) of the resistive film 41 (i.e., thicknesses of the first and second resistive portions 411, 412) is also critical to ensure that the resistive feature 44 and the interconnect feature 45 has desirable electrical properties and performance. For instance, if T2 is too small, electrical resistivity of the resistive feature 44 may be adversely affected. If T1 is too large, or the ratio of T2 to T1 is too low, the electrical conductivity of the interconnect feature 45 may be undesirably reduced, and performance of the interconnect feature 45 may deteriorate. In view of the above, the resistive feature 44 of the present disclosure may serve as a resistor, while the interconnect feature 45 may serve as an interconnect element, such as a power line, a signal line, a via, but are not limited thereto. Other suitable applications of the resistive feature 44 and/or the interconnect feature 45 are within the contemplated scope of the present disclosure.

Referring to FIG. 16, a second interconnect level M1 is formed on, and is connected to, the first interconnect level M0. The second interconnect level M1 includes conductive features 63, 64 formed in a dielectric feature. The dielectric feature includes an etch stop layer 61 and a dielectric layer 62. In some embodiments, the conductive features 64 may each serve as a metal line, and the conductive feature 63 may serve as a metal via. It is noted that the second interconnect level M1 is exemplarily connected to the first resistive portion 411 through the second conductive part 431B of the first conductive portion 431, and the conductive feature 63. In the resistive feature 44 (i.e., a thin-film resistor), the first resistive portion 411 is directly connected to the second conductive part 431B (see also FIG. 12), and has a relatively larger contact area therebetween in comparison with the case that a thicker resistor is directly connected to a metal via, and thus has a much smaller contact area therebetween. In some embodiments, the contact area between the first resistive portion 411 and the second conductive part 431B is at least about 5 times (e.g., about 10 times, about 15 times, or about 20 times) greater than the contact area between the thicker resistor and the metal via. Therefore, a contact resistance between the first resistive portion 411 and the second interconnect level M1 is significantly low. Such low contact resistance is beneficial in enhancing operation speed of the semiconductor structure obtained by the method of the present disclosure.

In some embodiments, an etch stop material layer (not shown, for forming the etch stop layer 61) and a dielectric material layer (not shown, for forming the dielectric layer 62) are first formed over the structure shown in FIG. 15 using suitable deposition processes, and then a dual damascene process, or other suitable patterning processes are performed, so as to obtain the etch stop layer 61, the dielectric layer 62, and the conductive features 63, 64. In the dual damascene process, a barrier material and a conductive material are sequentially deposited, such that each of the conductive features 63, 64 may include a barrier portion 65 (made of the barrier material) surrounding a conductive portion 66 (made of the conductive material). In some embodiments, an inhibitor may be involved, so that the barrier portion 65 is not formed beneath the conductive feature 63, and the conductive feature 63 interconnects the first and second interconnect levels M0, M1.

The etch stop layer 61 may include or may be made of a dielectric material such as an aluminum-based material (e.g., aluminum oxide, aluminum nitride, aluminum oxycarbide), silicon carbide, silicon nitride, silicon carbonitride, silicon oxynitride, other suitable materials, or combinations thereof. Possible materials for forming the dielectric layer 62 are similar to those of the dielectric layer 35, and thus details thereof are omitted for the sake of brevity. Examples of the barrier material include a metal nitride such as tantalum nitride, titanium nitride, tungsten nitride; a metal oxide such as hafnium oxide; a metal such as, tantalum, zinc, manganese, zirconium, titanium, hafnium, niobium, vanadium, chromium, scandium, yttrium, aluminum, cobalt, or combinations thereof. Examples of the conductive material may include copper, silver, gold, aluminum, nickel, cobalt, ruthenium, iridium, platinum, palladium, osmium, tungsten, molybdenum, tantalum, or combinations thereof. Other suitable materials for forming the etch stop layer 61, the dielectric layer 62, the barrier portion 65 and the conductive portion 66 are within the contemplated scope of the present disclosure.

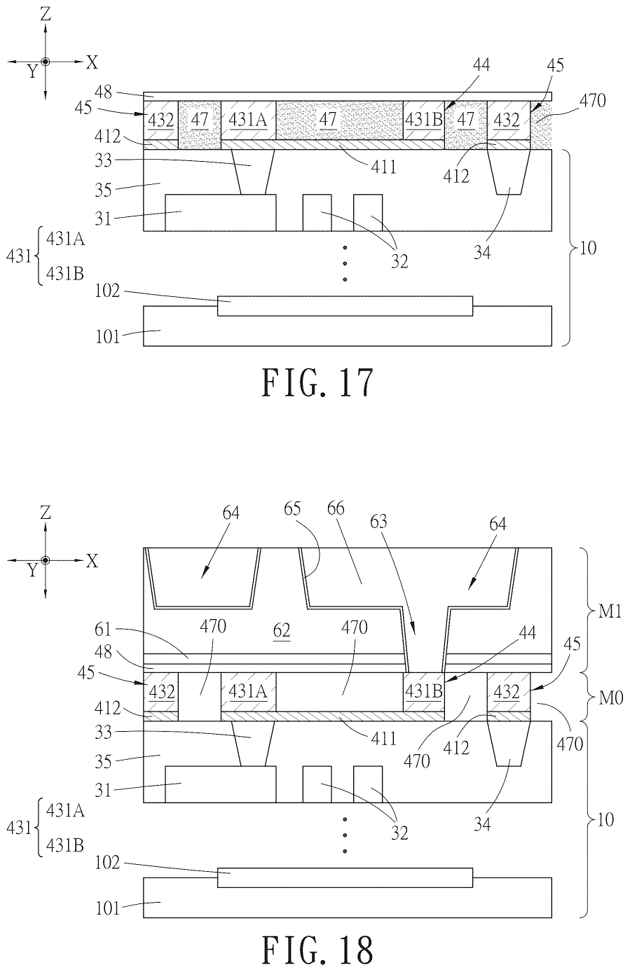

FIGS. 17 and 18 illustrate alternative steps to those shown in FIGS. 15 and 16, respectively. Please note that one may decide to use a low k-dielectric approach shown in FIGS. 15 and 16, or an air gap approach shown in FIGS. 17 and 18 according to practical needs.

Referring to FIG. 17, a sacrificial layer 47 and a sustaining layer 48 are sequentially formed over the structure shown in FIG. 10.

The sacrificial layer 47 may be formed using a suitable deposition process, followed by a planarization process (e.g., CMP, but is not limited thereto), so that the conductive pattern (i.e., the first and second conductive portions 431, 432) are exposed from the sacrificial layer 47. Top surfaces of the sacrificial layer 47 and the conductive pattern are flush with each other. Then the sustaining layer 48 is formed over the sacrificial layer 47 and the conductive pattern using a suitable deposition process.

The sacrificial layer 47 may include or be made of a hydrocarbon-based polymer e.g. polyurea, polylactic acid, polycaprolactone, poly(ethylene oxide), polyacrylate, polyvinyl alcohol, poly(methyl methacrylate), or combinations thereof. The sustaining layer 48 may include or be made of a low-k dielectric material e.g. silicon oxide, silicon nitride, silicon carbide, silicon oxycarbide, silicon oxynitride, silicon carbonitride, silicon oxycarbonitride, or combinations thereof. Other suitable materials for forming the sacrificial layer 47 and the sustaining layer 48 are within the contemplated scope of the present disclosure.

Referring to FIG. 18, the sacrificial layer 47 is removed to form air gaps 470, and the first and second interconnect levels M0, M1 are sequentially formed on the base structure 10.

The sacrificial layer 47 may be removed using a suitable process, such as a thermal decomposition process, an ultraviolet treatment, or a combination thereof. As such, the sacrificial layer 47 is removed and leave the air gaps 470 formed among the resistive feature(s) 44 and/or the interconnect feature(s) 45, and within the resistive feature(s) 44 (i.e., one of the air gaps 470 is enclosed by the first conductive portion 431, the first resistive portion 411 and the sustaining layer 48). That is, the resistive feature 44 and the interconnect features 45 are separated from one another by the air gaps 470.

After forming the air gaps 470, the second interconnect level M1 are formed. Possible materials and/or processes for forming the etch stop layer 61, the dielectric layer 62, and the conductive features 63, 64 are similar to those described in FIG. 16, and thus details thereof are omitted for the sake of brevity.

Step 101 in the flow diagram shown in FIG. 1 is exemplified by the structure shown in FIG. 3. Step 102 in the flow diagram shown in FIG. 1 is exemplified by the structures shown in FIGS. 4 to 5. Step 103 in the flow diagram shown in FIG. 1 is exemplified by the structures shown in FIGS. 6 to 14. FIGS. 15 to 16 illustrate possible steps subsequent to step 103 in accordance with some embodiments, thereby forming the semiconductor structure in accordance with some embodiments. FIGS. 17 to 18 illustrate some other possible steps subsequent to step 103 in accordance with some other embodiments.

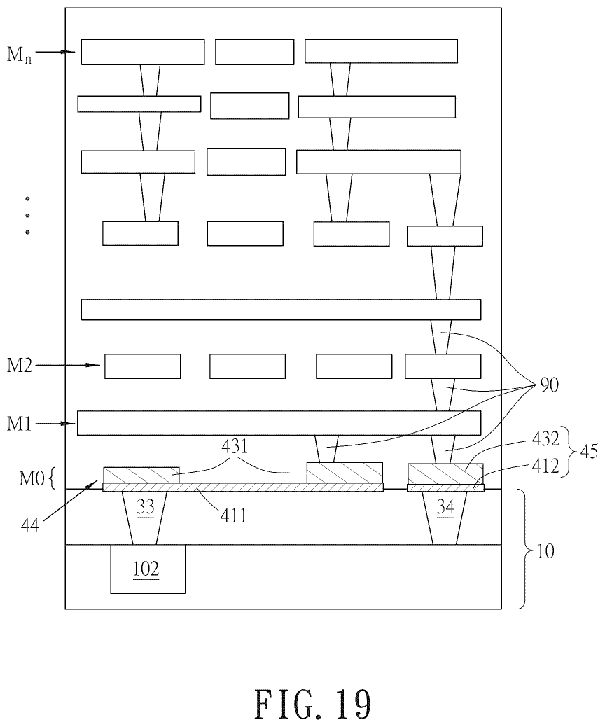

Other interconnect levels may be further formed on the semiconductor structures obtained in FIGS. 16 and 18 according to practical needs. FIG. 19 is a schematic diagram illustrating configuration of the interconnect levels. For instance, the interconnect levels M0, M1, M2 . . . Mn may be connected to each other through vias 90. As exemplarily shown in FIGS. 16, 18 and 19, it is possible to form the resistive feature 44 in the interconnect level M0 that is connected to the semiconductor devices 102 through the conductive feature 33 located at a middle-end-of-line (MEOL) section. Such configuration permits a connection path between the resistive feature 44 and the semiconductor device 102 to be relatively short, thereby ensuring a low resistance level of the connection path and a high operation speed. In some other embodiments, the formation of the resistive feature 44 and the interconnect feature 45 may also be applied in higher interconnect level, e.g., M1, M2, Mn, or other suitable level.

In some cases, the resistive feature is formed with a relatively thick thickness, and is inserted between two adjacent ones of the interconnect levels. Specifically, after forming a lower one of the two adjacent interconnect levels, the resistive feature that is relatively thick is formed on a certain region of the lower interconnect level. Such resistive feature undesirably causes additional protrusion on the lower interconnect level, leading to topography concern, e.g., causing local stress and impact to interconnect levels nearby. In addition, metal lines which are immediately adjacent to such resistive feature are configured as floating metal lines that are not electrically connected to other conducting elements of the semiconductor structure, so as to avoid reliability and/or thermal issues and/or impacts to electrical properties of other conducting elements nearby. The connection path between such resistive feature and the semiconductor device is relatively long, and undesirably causes RC delay, unwanted power consumption and low operation speed.

In contrast, in the present disclosure, the resistive film 41 is formed with a relatively thin thickness, and does not cause the aforementioned topography issue. The floating metal lines may be omitted in the present disclosure, i.e., metal lines that are adjacent to the resistive feature 44, e.g., the conductive features 64, as shown in FIGS. 16 and 18, may be configured as routing metal lines for signal transmission, or other suitable interconnect purposes. In addition, the resistive feature 44 and the interconnect feature 45 are formed within the same interconnect level using the same patterning mask (or known as a clear-out photomask, which is used in the second patterning process). Formation of such resistive feature 44 is simple and does not require additional masks or complex processes. Since the resistive feature 44 and the interconnect feature 45 are simultaneously formed, the resistive feature 44 is also known as a self-formed resistive feature.

In sum, in the method of the present disclosure, the resistive feature 44 and the interconnect feature 45 are formed by patterning of the resistive film 41 and the conductive layer 42, which utilizes simple etching processes and the same etching mask (i.e., without employing additional masks). The resistive feature 44 thus obtained is significantly thin and avoids topography issue in the semiconductor structure. In addition, the resistive feature 44 may be placed close to the semiconductor device 102 to ensure that the conduction path therebetween is short. Moreover, within the resistive feature 44 (i.e., a thin-film resistor), the first resistive portion 411 is in contact with the first conductive portion 431, and a contact surface therebetween is relatively large in comparison with the case that a resistor having a large thickness is in contact with a metal via, and thus a contact resistance between the first resistive portion 411 and the second interconnect level M1 is significantly low. As such, the semiconductor structure may have a high operation speed.

In accordance with some embodiments of the present disclosure, a method for manufacturing a semiconductor structure includes: sequentially forming a resistive film and a conductive layer over a base structure; performing a first patterning process to form the conductive layer into a patterned conductive layer without patterning the resistive film; and performing a second patterning process to form the patterned conductive layer into a conductive pattern, and to form the resistive film into a resistive pattern, the resistive pattern having a first resistive portion including a first resistive part that has a first end, a second end, and a main region disposed between the first end and the second end, the conductive pattern having a first conductive portion including a first conductive part that is disposed on the first end of the first resistive part without covering the main region, and the first resistive portion and the first conductive portion together forming a resistive feature.

In accordance with some embodiments of the present disclosure, the first conductive portion further includes a second conductive part that is disposed on the second end of the first resistive part without covering the main region.

In accordance with some embodiments of the present disclosure, the first end and the second end of the first resistive part are opposite to each other in a first direction; the first resistive portion further has a second resistive part that has a first end, a second end, and a main region disposed between the first end and the second end; the main region of the second resistive part is spaced apart from the main region of the first resistive part in a second direction different from the first direction; the second end of the first resistive part and the second end of the second resistive part are connected to each other in the second direction; and the first conductive portion further has two second conductive parts that cover the second end of the first resistive part and the second end of the second resistive parts, respectively, without covering the main region of the first resistive part and the main region of the second resistive part.

In accordance with some embodiments of the present disclosure, the two second conductive parts are connected to each other in the second direction.

In accordance with some embodiments of the present disclosure, the resistive pattern further includes a second resistive portion that is spaced apart from the first resistive portion; the conductive pattern further includes a second conductive portion that is disposed on the second resistive portion; and the second resistive portion and the second conductive portion together forms an interconnect feature.

In accordance with some embodiments of the present disclosure, a resistivity of the resistive feature is greater than a resistivity of the interconnect feature.

In accordance with some embodiments of the present disclosure, the resistive feature and the interconnect feature are formed simultaneously.

In accordance with some embodiments of the present disclosure, in the first patterning process, an etching rate of the conductive layer is higher than an etching rate of the resistive film.

In accordance with some embodiments of the present disclosure, the resistive film has a thickness ranging from 10 Å to 50 Å.

In accordance with some embodiments of the present disclosure, the conductive layer has a thickness ranging from 100 Å to 400 Å.

In accordance with some embodiments of the present disclosure, a method for manufacturing a semiconductor structure includes: sequentially forming a resistive film and a conductive layer over a base structure; and performing a patterning process to form the conductive layer into a conductive pattern, and to form the resistive film into a resistive pattern, the resistive pattern having a first resistive portion, the conductive pattern having a first conductive portion, and the first conductive portion occupying not greater than 30% of an area of a top surface of the first resistive portion.

In accordance with some embodiments of the present disclosure, a resistivity of the resistive film is higher than a resistivity of the conductive layer.

In accordance with some embodiments of the present disclosure, the method further includes: forming a sacrificial layer over the resistive pattern, the conductive pattern being exposed from the sacrificial layer; forming a sustaining layer over the sacrificial layer and the conductive pattern; removing the sacrificial layer, so as to form an air gap; forming a dielectric feature over the sustaining layer; and forming a conductive feature in the dielectric feature, the conductive feature penetrating the sustaining layer to be connected to the first conductive portion.

In accordance with some embodiments of the present disclosure, the method further includes: forming a dielectric layer over the resistive pattern, the conductive pattern being exposed from the dielectric layer; forming a dielectric feature over the dielectric layer and the conductive pattern; and forming a conductive feature in the dielectric feature, the conductive feature being connected to the first conductive portion.

In accordance with some embodiments of the present disclosure, the resistive pattern further includes a second resistive portion that is spaced apart from the first resistive portion; the conductive pattern further includes a second conductive portion that is disposed on the second resistive portion; and the second resistive portion and the second conductive portion together forms an interconnect feature.

In accordance with some embodiments of the present disclosure, the second conductive portion occupies not less than 90% of an area of a top surface of the second resistive portion.

In accordance with some embodiments of the present disclosure, the resistive film includes titanium nitride, titanium oxide, titanium oxynitride, tantalum nitride, tantalum oxide, tungsten carbon nitride, zirconium oxide, cobalt oxide, silicon nitride, boron nitride, or combinations thereof.

In accordance with some embodiments of the present disclosure, the conductive layer includes ruthenium, tungsten, molybdenum, iridium, nickel aluminum, cobalt platinum, or combinations thereof.

In accordance with some embodiments of the present disclosure, a semiconductor structure includes a base structure; and an interconnect level disposed on the base structure. The interconnect level includes a resistive feature and an interconnect feature that is spaced apart from the resistive feature. The resistive feature includes a first conductive portion and a first resistive portion that is partially covered by the first conductive portion. The interconnect feature includes a second conductive portion and a second resistive portion that is entirely covered by the second conductive portion.

In accordance with some embodiments of the present disclosure, a resistivity of the resistive feature is higher than a resistivity of the interconnect feature.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
sequentially forming a resistive film and a conductive layer over a base structure;
performing a first patterning process to form the conductive layer into a patterned conductive layer without patterning the resistive film; and
performing a second patterning process to form the patterned conductive layer into a conductive pattern, and to form the resistive film into a resistive pattern,
the resistive pattern having a first resistive portion including a first resistive part that has a first end, a second end, and a main region disposed between the first end and the second end,
the conductive pattern having a first conductive portion including a first conductive part that is disposed on the first end of the first resistive part without covering the main region, and
the first resistive portion and the first conductive portion together forming a resistive feature.

2. The method of claim 1, wherein the first conductive portion further includes a second conductive part that is disposed on the second end of the first resistive part without covering the main region.

3. The method of claim 1, wherein:
the first end and the second end of the first resistive part are opposite to each other in a first direction;
the first resistive portion further has a second resistive part that has a first end, a second end, and a main region disposed between the first end and the second end;
the main region of the second resistive part is spaced apart from the main region of the first resistive part in a second direction different from the first direction;
the second end of the first resistive part and the second end of the second resistive part are connected to each other in the second direction; and
the first conductive portion further has two second conductive parts that cover the second end of the first resistive part and the second end of the second resistive parts, respectively, without covering the main region of the first resistive part and the main region of the second resistive part.

4. The method of claim 3, wherein the two second conductive parts are connected to each other in the second direction.

5. The method of claim 1, wherein:
the resistive pattern further includes a second resistive portion that is spaced apart from the first resistive portion;
the conductive pattern further includes a second conductive portion that is disposed on the second resistive portion; and
the second resistive portion and the second conductive portion together forms an interconnect feature.

6. The method of claim 5, wherein a resistivity of the resistive feature is greater than a resistivity of the interconnect feature.

7. The method of claim 5, wherein the resistive feature and the interconnect feature are formed simultaneously.

8. The method of claim 1, wherein, in the first patterning process, an etching rate of the conductive layer is higher than an etching rate of the resistive film.

9. The method of claim 1, wherein the resistive film has a thickness ranging from 10 Å to 50 Å.

10. The method of claim 1, wherein the conductive layer has a thickness ranging from 100 Å to 400 Å.

11. A method for manufacturing a semiconductor structure, comprising:
sequentially forming a resistive film and a conductive layer over a base structure; and
performing a patterning process to form the conductive layer into a conductive pattern, and to form the resistive film into a resistive pattern,
the resistive pattern having a first resistive portion,
the conductive pattern having a first conductive portion, and
the first conductive portion occupying not greater than 30% of an area of a top surface of the first resistive portion.

12. The method of claim 11, wherein a resistivity of the resistive film is higher than a resistivity of the conductive layer.

13. The method of claim 11, further comprising:
forming a sacrificial layer over the resistive pattern, the conductive pattern being exposed from the sacrificial layer;
forming a sustaining layer over the sacrificial layer and the conductive pattern;
removing the sacrificial layer, so as to form an air gap;
forming a dielectric feature over the sustaining layer; and
forming a conductive feature in the dielectric feature, the conductive feature penetrating the sustaining layer to be connected to the first conductive portion.

14. The method of claim 11, further comprising:
forming a dielectric layer over the resistive pattern, the conductive pattern being exposed from the dielectric layer;
forming a dielectric feature over the dielectric layer and the conductive pattern; and
forming a conductive feature in the dielectric feature, the conductive feature being connected to the first conductive portion.

15. The method of claim 11, wherein:
the resistive pattern further includes a second resistive portion that is spaced apart from the first resistive portion;
the conductive pattern further includes a second conductive portion that is disposed on the second resistive portion; and
the second resistive portion and the second conductive portion together forms an interconnect feature.

16. The method of claim 15, wherein the second conductive portion occupies not less than 90% of an area of a top surface of the second resistive portion.

17. The method of claim 11, wherein the resistive film includes titanium nitride, titanium oxide, titanium oxynitride, tantalum nitride, tantalum oxide, tungsten carbon nitride, zirconium oxide, cobalt oxide, silicon nitride, boron nitride, or combinations thereof.

18. The method of claim 11, wherein the conductive layer includes ruthenium, tungsten, molybdenum, iridium, nickel aluminum, cobalt platinum, or combinations thereof.

19. A semiconductor structure, comprising:
a base structure; and
an interconnect level disposed on the base structure, the interconnect level including a resistive feature and an interconnect feature that is spaced apart from the resistive feature,
the resistive feature including a first conductive portion and a first resistive portion that is partially covered by the first conductive portion, and
the interconnect feature including a second conductive portion and a second resistive portion that is entirely covered by the second conductive portion.

20. The method of claim 19, wherein a resistivity of the resistive feature is higher than a resistivity of the interconnect feature.
